(19) United States
(12) Patent Application Publication
(10) Pub. No.: US 2026/0082618 A1
(43) Pub. Date: Mar. 19, 2026

(54) LDMOS AND FABRICATING METHOD OF THE SAME

(71) Applicant: UNITED MICROELECTRONICS CORP., Hsin-Chu City (TW)

(72) Inventors: Ze-Wei Jhou, Hsinchu County (TW); Chen-An Kuo, Taoyuan City (TW); Ke-Feng Lin, Taipei City (TW); Chiu-Te Lee, Hsinchu County (TW); Yan-Huei Li, Taichung City (TW); Ji-Jie Luo, Miaoli County (TW); Hsin-Che Huang, Tainan City (TW); Huey-Jong Su, Hsinchu City (TW)

(73) Assignee: UNITED MICROELECTRONICS CORP., Hsin-Chu City (TW)

(21) Appl. No.: 18/926,269

(22) Filed: Oct. 24, 2024

(30) Foreign Application Priority Data
Sep. 16, 2024 (TW) 113135040

(51) Int. Cl. H01L 29/78; H01L 29/06; H01L 29/423; H01L 29/49; H01L 29/66

(52) U.S. Cl. CPC H10D 30/65; H10D 30/0281; H10D 62/102; H10D 64/518; H10D 64/663

(57) ABSTRACT

An LDMOS includes a substrate. A gate electrode is disposed on the substrate. A first gate dielectric layer is disposed between the gate electrode and the substrate. A second gate dielectric layer includes a first part and a second part. A source is embedded in the substrate at one side of the gate electrode. A drain is embedded in the substrate at the other side of the gate electrode. The second part of the second gate dielectric layer is extended toward the drain along a horizontal direction. The first part is covered by the gate electrode, and the second part is not covered by the gate electrode. Along the horizontal direction, the first part has a first length, and the second part has a second length. The second length is adjustable for adjusting a breakdown voltage of the LDMOS.

### BACKGROUND OF THE INVENTION

### 1. Field of the Invention

The present invention relates to a laterally diffused metal oxide semiconductor, (LDMOS), and in particular to an LDMOS that adjusts a breakdown voltage by adjusting a length of a gate dielectric layer and a fabricating method of the same.

### 2. Description of the Prior Art

LDMOS has the characteristics of high breakdown voltage and compatibility with complementary metal oxide semiconductor technology in low voltage devices. Therefore, LDMOS is used in many applications, such as for mobile phones, ADSL drivers, LED displays, LCD display drivers, high power amplifiers for wireless base stations, and other power management.

The main characteristics of the LDMOS are low doping concentration and drift regions with large areas. These characteristics are to alleviate the high voltage between the source and the drain, so that the LDMOS can obtain a higher breakdown voltage.

In the semiconductor manufacturing process, the layout design of the LDMOS provided by the customer must comply with the design rules of the wafer manufacturer, and design rules vary from manufacturer to manufacturer. Due to the need to comply with design rules, some parameters of the LDMOS cannot be fine-tuned based on the customer's requirements.

### SUMMARY OF THE INVENTION

In view of this, the present invention provides an LDMOS with an adjustable length of a gate dielectric layer to provide customers with greater freedom in the design of the LDMOS.

According to a preferred embodiment of the present invention, an LDMOS includes a substrate, wherein a horizontal direction is parallel to a top surface of the substrate, and a vertical direction is perpendicular to the top surface of the substrate. A gate electrode is disposed on the substrate. A first gate dielectric layer is disposed between the gate electrode and the substrate. A second gate dielectric layer includes a first part and a second part, wherein a first part is disposed below the gate electrode and connected to the first gate dielectric layer, and a thickness of the second gate dielectric layer is greater than a thickness of the first gate dielectric layer. A source is embedded in the substrate at one side of the gate electrode. A drain is embedded in the substrate at the other side of the gate electrode; wherein the second part of the second gate dielectric layer is extended toward the drain along the horizontal direction, the first part is covered by the gate electrode, the second part is not covered by the gate electrode, and wherein along the horizontal direction, the first part has a first length, and the second part has a second length, and the second length is adjustable for adjusting a breakdown voltage of the LDMOS.

According to another preferred embodiment of the present invention, a fabricating method of an LDMOS includes providing a substrate, wherein a horizontal direction is parallel to a top surface of the substrate, and a vertical direction is perpendicular to the top surface of the substrate. Next, a second gate dielectric material layer is formed to cover the substrate. Later, the second gate dielectric material layer is patterned to form a second gate dielectric layer. After forming the second gate dielectric layer, a first gate dielectric material layer is formed to cover the substrate. After that, the first gate dielectric material layer is patterned to form a first gate dielectric layer which is connected to the second gate dielectric layer, wherein a thickness of the second gate dielectric layer is greater than a thickness of the first gate dielectric layer. Subsequently, a gate electrode is formed to cover the first gate dielectric layer and the second gate dielectric layer. Finally, a source and a drain are formed respectively to be embedded in the substrate at two sides of the gate electrode. The second gate dielectric layer has a first part and a second part, the second part is extended toward the drain along the horizontal direction, the first part is covered by the gate electrode, and the second part is not covered by the gate electrode, and along the horizontal direction, the first part has a first length, the second part has a second length, and the second length is adjustable for adjusting a breakdown voltage of the LDMOS.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 depict a fabricating method of an LDMOS according a first preferred embodiment of the present invention, wherein:

FIG. 2 depicts a fabricating stage subsequent to FIG. 1;

FIG. 3 depicts a fabricating stage subsequent to FIG. 2;

FIG. 4 depicts a fabricating stage subsequent to FIG. 3;

FIG. 5 depicts a fabricating stage subsequent to FIG. 4;

FIG. 6 depicts a fabricating stage subsequent to FIG. 5;

FIG. 7 depicts a fabricating stage subsequent to FIG. 6; and

FIG. 8 depicts a fabricating stage subsequent to FIG. 7.

FIG. 9 depicts a varied type of an LDMOS according to the first preferred embodiment of the present invention.

FIG. 10 depicts another varied type of an LDMOS according to the first preferred embodiment of the present invention.

FIG. 11 depicts a fabricating method of an LDMOS according to a second preferred embodiment of the present invention.

### DETAILED DESCRIPTION

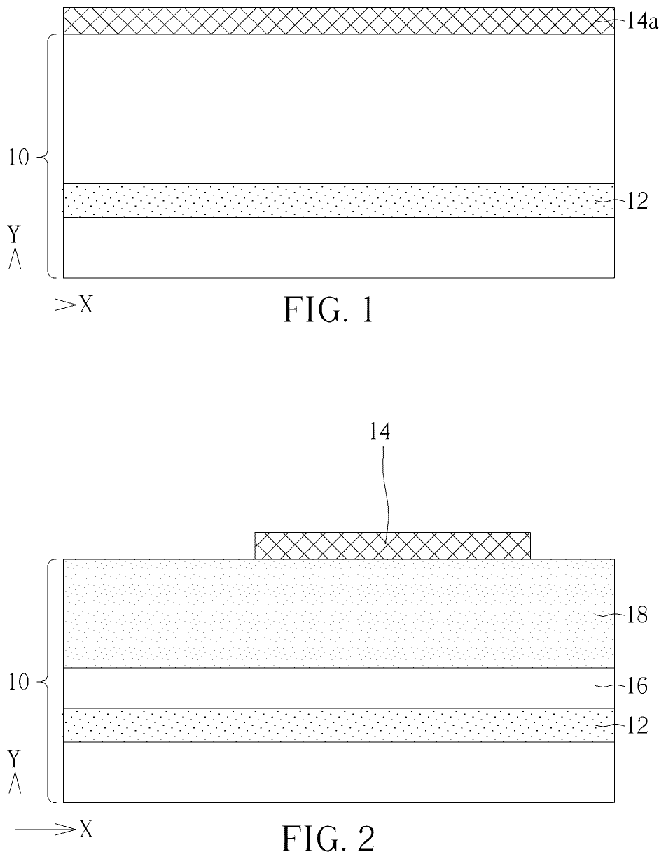

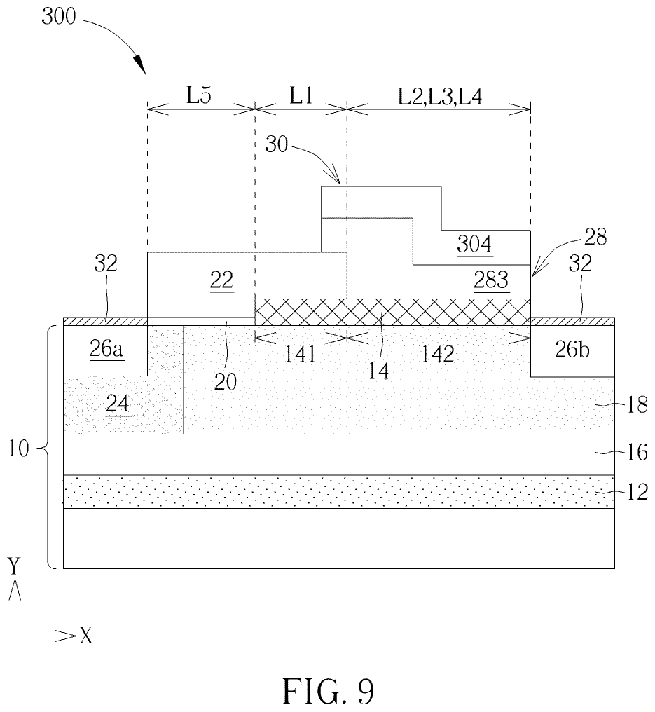

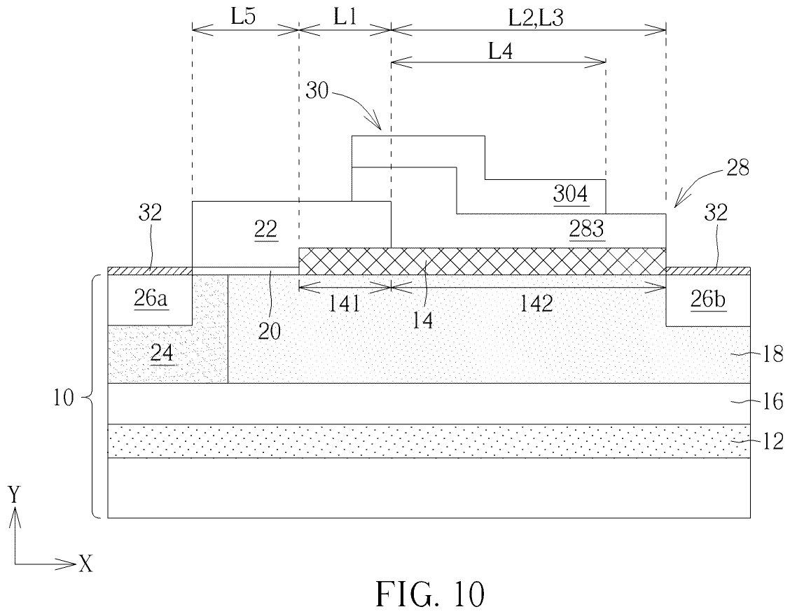

FIG. 1 to FIG. 8 depict a fabricating method of an LDMOS according a first preferred embodiment of the present invention. FIG. 9 depicts a varied type of an LDMOS according to the first preferred embodiment of the present invention. FIG. 10 depicts another varied type of an LDMOS according to the first preferred embodiment of the present invention.

As shown in FIG. 1, a substrate 10 is provided. A horizontal direction X is parallel to a top surface of the substrate 10. A vertical direction Y is perpendicular to the top surface of the substrate 10. Then, an ion implantation process is performed to form a first deep doping well 12 in the substrate 10. The first deep doping well 12 may be N-type or P-type. Later, a deposition process is performed to form a second gate dielectric material layer 14a. As shown in FIG. 2, another ion implantation process is performed to form a second deep doping well 16 in the substrate 10. The depth of the second deep doping well 16 is shallower than the depth of the first deep doping well 12. The second deep doping well 16 may be P-type or N-type. Next, another ion implantation process is performed to form a drift region 18 in the substrate 10. The drift region 18 may be N-type or P-type. After that, the second gate dielectric material layer 14a is patterned to form a second gate dielectric layer 14.

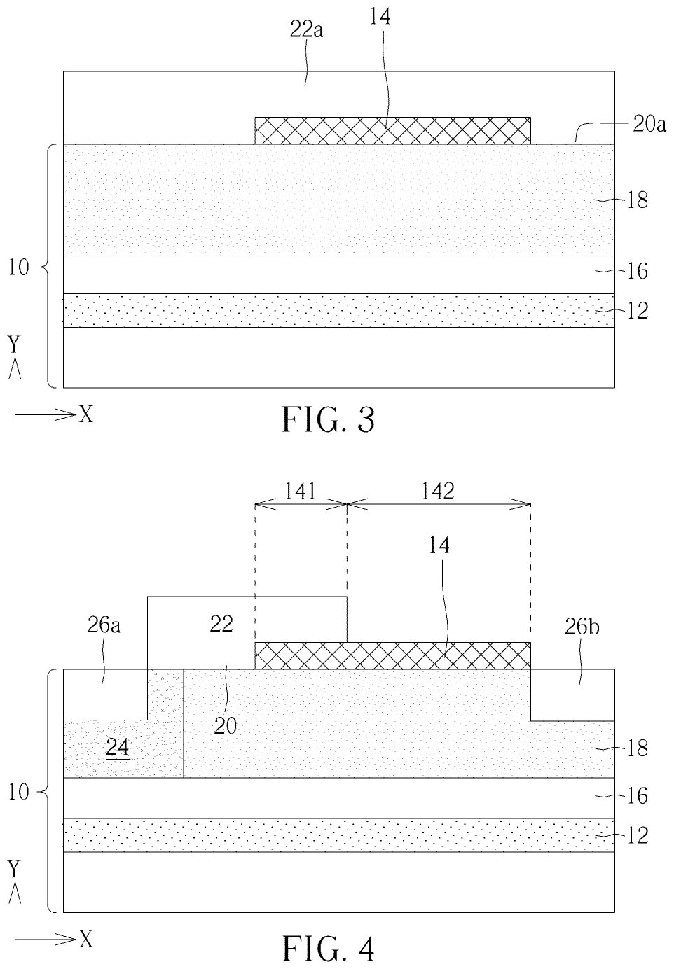

As shown in FIG. 3, a first gate dielectric material layer 20a is formed to cover the substrate 10. The first gate dielectric material layer 20a is preferably formed by using a thermal process. According to different requirements, the first gate dielectric material layer 20a may also be formed by using a deposition process. If a deposition process is used to form the first gate dielectric material layer 20a, the first gate dielectric material layer 20a will cover the substrate 10 and the second gate dielectric layer 14. In this embodiment, the first gate dielectric material layer 20a is formed by using a thermal process. Later, a gate electrode material layer 22a is formed to cover the first gate dielectric material layer 20a and the second gate dielectric layer 14.

As shown in FIG. 4, the gate electrode material layer 22a and the first gate dielectric material layer 20a are patterned by using the same photomask to form a gate electrode 22 and a first gate dielectric layer 20. Next, spacers (not shown) are formed on the sidewalls of the gate electrode 22. Now, the gate electrode 22 covers all the first gate dielectric layer 20 and part of the second gate dielectric layer 14. Therefore, a part of the second gate dielectric layer 14 is not covered by the gate electrode 22. The second gate dielectric layer 14 not covered by the gate electrode 22 is defined as a second part 142. The second gate dielectric layer 14 covered by the gate electrode 22 is defined as a first part 141. The thickness of the second gate dielectric layer 14 is greater than the thickness of the first gate dielectric layer 20. Subsequently, an ion implantation process is performed to form a body region 24. The body region 24 may be P-type or N-type. Then, another ion implantation process is performed to simultaneously form a source 26a and a drain 26b respectively embedded in the substrate 10 at two sides of the gate electrode 22. The source 26a is adjacent to the first gate dielectric layer 20, and the drain 26b is adjacent to the second gate dielectric layer 14. The source 26a and the drain 26b have the same conductivity type, such as N-type or P-type. The source 26a is disposed in body region 24. The drain 26b is disposed in the drift region 18. The interface between the body region 24 and the drift region 18 is located directly below the first gate dielectric layer 20. In this embodiment, the conductive types of the first deep doping well 12, the drift region 18, the source 26a and the drain 26b are the same. The second deep doping well 16 and the body region 24 have the same conductivity type. For example, when the first deep doping well 12, the drift region 18, the source 26a and the drain 26b are N-type, the second deep doping well 16 and the body region 24 are P-type. In different embodiments, when the first deep doping well 12, the drift region 18, the source 26a and the drain 26b are P-type, the second deep doping well 16 and the body region 24 can be N-type.

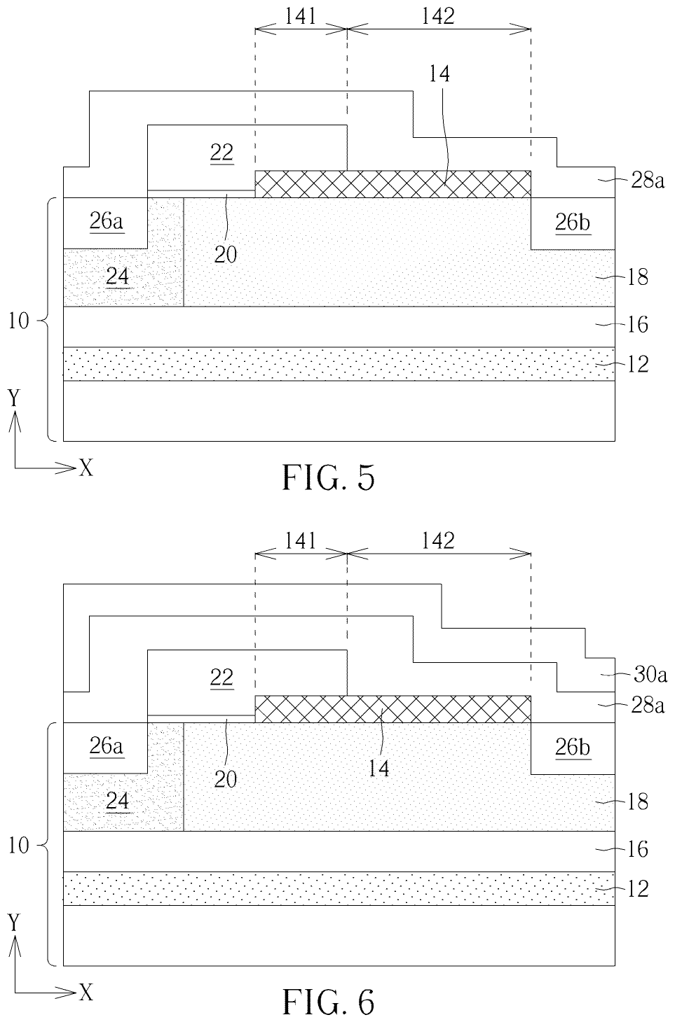

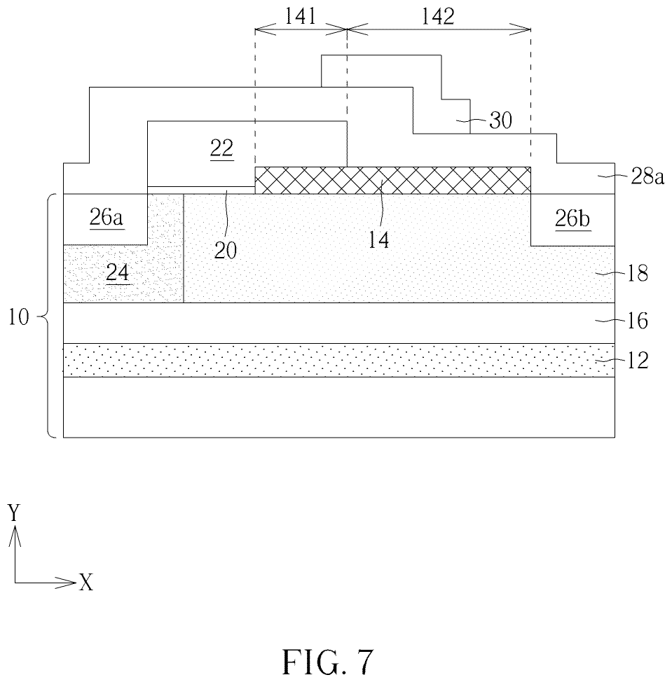

As shown in FIG. 5, a silicide block layer 28a is formed blankly to cover and contact the gate electrode 22, the second part 142 of the second gate dielectric layer 14, the source 26a and the drain 26b. As shown in FIG. 6, a polysilicon material layer 30a is formed blankly to cover and contact the silicide block material layer 28a. As shown in FIG. 7, the polysilicon material layer 30a is patterned to form a polysilicon layer 30. The polysilicon layer 30 covers a portion of the second part 142 of the second gate dielectric layer 14 and a portion of the gate electrode 22. That is, the polysilicon layer 30 covers the channel which is below the gate electrode 22 and between the gate electrode 22 and the drain 26b. The polysilicon layer 30 serves as a field plate for dispersing the electric field around a corner of the gate electrode 22, and the corner is closed to the drain 26b. Therefore, the breakdown voltage of the LDMOS can be increased. According to different product requirements, the length of the polysilicon layer 30 along the horizontal direction X can be adjusted to modulate the breakdown voltage of the LDMOS.

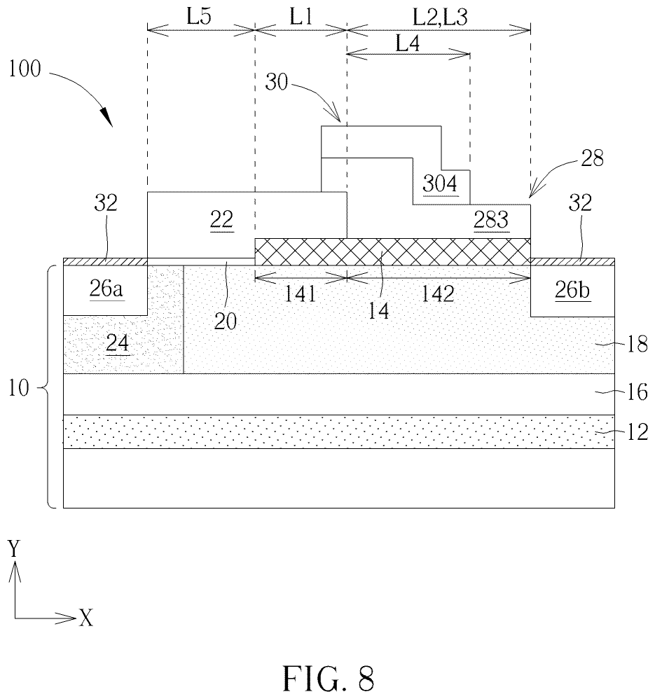

As shown in FIG. 8, the silicide block material layer 28a is patterned to form a silicide block layer 28. The silicide block layer 28 covers and contacts a portion of the gate electrode 22 and all the top surface of the second part 142 of the second gate dielectric layer 14. In addition, the source 26a and the drain 26b are exposed through the silicide block layer 28. Then, two silicide layers 32 are formed to cover the source 26a and the drain 26b respectively. The silicide layers 32 include nickel silicide (NiSi), platinum silicide (PtSi), titanium disilicide (TiSi₂), or tungsten disilicide (WSi₂). If the gate electrode 22 is made of polysilicon, the silicide layers 32 will also be formed on the top surface of the gate electrode 22. Now, an LDMOS 100 of the present invention is completed.

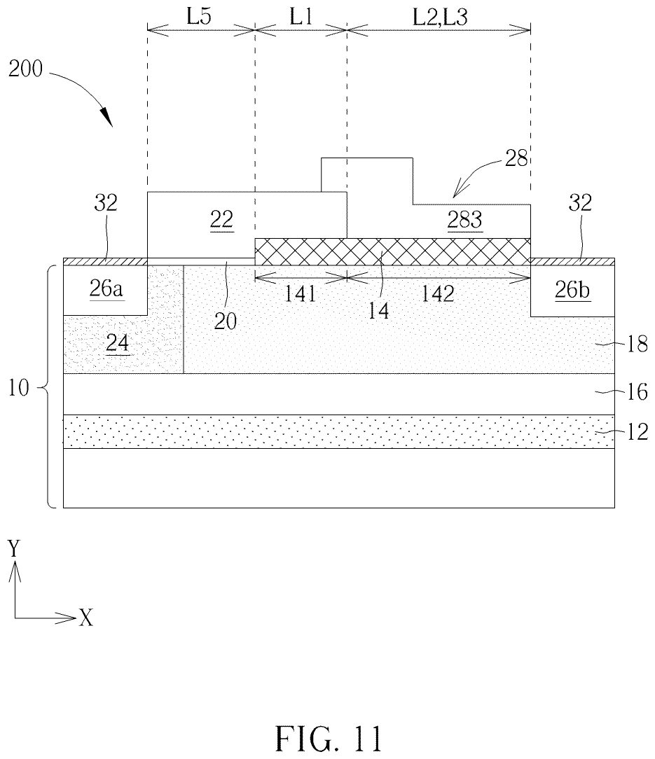

FIG. 11 depicts a fabricating method of an LDMOS according to a second preferred embodiment of the present invention. FIG. 11 depicts a fabricating step in continuous of FIG. 5. The difference between the second preferred embodiment and the first preferred embodiment is that the second preferred embodiment does not have the polysilicon layer 30, therefore only the silicide block material layer 28a needs to be patterned. As shown in FIG. 11, the silicide block material layer 28a is patterned to form a silicide block layer 28. The silicide block layer 28 covers and contacts a portion of the gate electrode 22 and all the top surface of the second part 142 of the second gate dielectric layer 14. In addition, the source 26a and the drain 26b are exposed through the silicide block layer 28. Later, two silicide layers 32 are formed to cover the source 26a and the drain 26b respectively. Now, an LDMOS 200 of the present invention is completed. In the second preferred embodiment, elements are substantially the same as those in the first preferred embodiment are denoted by the same reference numerals; an accompanying explanation is therefore omitted. In the second preferred embodiment, although the LDMOS 200 does not use the polysilicon layer 30 as a field plate, the second gate dielectric layer 14 can be used to increase the breakdown voltage between the gate electrode 22 and the drain 26b.

As shown in FIG. 8, an LDMOS 100 includes a substrate 10. A horizontal direction X is parallel to the top surface of the substrate 10. A vertical direction Y is perpendicular to the top surface of the substrate 10. The substrate 10 includes a silicon substrate, a germanium substrate, a gallium arsenide substrate, a silicon germanium substrate, an indium phosphide substrate, a gallium nitride substrate, a silicon carbide substrate or a silicon-on-insulator substrate. A gate electrode 22 is disposed on the substrate 10. The gate electrode 22 includes doped polysilicon, metal or alloy. A first gate dielectric layer 20 is disposed between the gate electrode 22 and the substrate 10. A second gate dielectric layer 14 includes a first part 141 and a second part 142. The first part 141 is disposed below the gate electrode 22 and connected to the first gate dielectric layer 20. The first part 141 is covered by the gate electrode 22. The second part 142 is not covered by the gate electrode 22. The thickness of the second gate dielectric layer 14 is greater than the thickness of the first gate dielectric layer 20. The first gate dielectric layer 20 and the second gate dielectric layer 14 are preferably silicon oxide, silicon nitride or silicon oxynitride. A source 26a is embedded in the substrate 10 at one side of the gate electrode 22, and a drain 26b is embedded in the substrate 10 at the other side of the gate electrode 22. The second part 142 of the second gate dielectric layer 14 extends toward the drain 26b along the horizontal direction X. The first part 141 has a first length L1 along the horizontal direction X, and the second part 142 has a second length L2 along the horizontal direction X. The second length L2 is greater than the first length L1. The second length is adjustable for adjusting a breakdown voltage of the LDMOS 100. Moreover, along the horizontal direction X, the first gate dielectric layer 20 includes a fifth length L5.

Furthermore, a silicide block layer 28 covers and contacts the gate electrode 22 and the entire top surface of the second part 142. The silicide block layer 28 may include silicon oxide. Moreover, the silicide block layer 28 includes a third part 283. The third part 283 does not overlap the gate electrode 22 along the vertical direction Y. Along the horizontal direction X, the third part 283 includes a third length L3. A polysilicon layer 30 covers and contacts the silicide block layer 28. The polysilicon layer 30 includes a fourth part 304. The fourth part 304 does not overlap the gate electrode 22 along the vertical direction Y. Along the horizontal direction X, the fourth part 304 includes a fourth length L4.

In addition, generally speaking, the layout design of the LDMOS provided by the customer needs to comply with the design rules of the wafer manufacturer. That is, the dimensions of various parts of the LDMOS, such as the length of the gate electrode, the positions of the source and drain, the width of the gate dielectric layer, etc., are not allowed to follow customer's layout design and must obey the fixed dimensions provided by the manufacturer.

However, the second length L2 of the second gate dielectric layer 14 in the present invention can be adjusted. The second length L2 can be adjusted to modulate the breakdown voltage of the LDMOS 100. In other words, the second length L2 can be changed within a certain range according to customer needs. Specifically speaking, when the manufacturer's design rules are determined, the first length L1 is a fixed value, and the fifth length L5 is also a fixed value. The dimensions of the LDMOS 100 are all fixed values except for the second length L2, the third length L3, the fourth length L4 and the width of the gate electrode 22. The second length L2 is 2 to 5 times of the first length L1. Therefore, the breakdown voltage and on-resistance of the LDMOS 100 can be customized by adjusting the second length L2. The fourth length L4 of the polysilicon layer 30 can be adjusted according to product requirements. For example, in FIG. 8, along the horizontal direction X, the fourth length L4 is smaller than the third length L3. Therefore, the end of the silicide block layer 28 close to the drain 26b is not covered by the polysilicon layer 30. As shown in FIG. 9, in the LDMOS 300, along the horizontal direction X, the fourth length L4 is equal to the third length L3. Therefore, the top surface of the silicide block layer 28 is covered by the polysilicon layer 30, and both ends of the silicide block layer 28 are aligned with both ends of the polysilicon layer 30. Based on different customer's requirements, if the second length L2 is adjusted, the third length L3 of the silicide block layer 28 and the fourth length L4 of the polysilicon layer 30 must be adjusted in equal scale with the adjustment of the second length L2 of the second gate dielectric layer 14.

Please refer to FIG. 8 and FIG. 10. As mentioned above, the third length L3 and the fourth length L4 must be adjusted in equal scale with the adjustment of the second length L2. For example, in FIG. 8, the second length L2 is twice of the first length L1. In FIG. 10, the second length L2 is adjusted to become 3 times of the first length L1. Therefore, the second length L2 in FIG. 10 is 1.5 times of the second length L2 in FIG. 8. In this way, the third length L3 in FIG. 10 is also 1.5 times of the third length L3 in FIG. 8, and the fourth length L4 in FIG. 10 is also 1.5 times of the fourth length in FIG. 8. In addition, the end of the second part 142 of the second gate dielectric layer 14 overlaps the edge of the drain 26b, and at least part of the drain 26b is not covered by the second part 142. When the second length L2 is adjusted, not only the third length L3 and the fourth length L4 are changed, but the position of the drain 26b also changes to be next to the end of the second part 142 of the second gate dielectric layer 14. In this way, the size of the entire LDMOS will also be changed.

In the present invention, the second gate dielectric layer not covered by the gate electrode has an adjustable second length. By adjusting the second length, the breakdown voltage and on-resistance of the LDMOS will also be changed. In this way, LDMOS can be customized based on different requirements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A laterally diffused metal oxide semiconductor (LDMOS), comprising:
a substrate, wherein a horizontal direction is parallel to a top surface of the substrate, and a vertical direction is perpendicular to the top surface of the substrate;
a gate electrode disposed on the substrate;
a first gate dielectric layer disposed between the gate electrode and the substrate;
a second gate dielectric layer comprising a first part and a second part, wherein a first part is disposed below the gate electrode and connected to the first gate dielectric layer, and a thickness of the second gate dielectric layer is greater than a thickness of the first gate dielectric layer;
a source embedded in the substrate at one side of the gate electrode; and
a drain embedded in the substrate at the other side of the gate electrode;
wherein the second part of the second gate dielectric layer is extended toward the drain along the horizontal direction, the first part is covered by the gate electrode, and the second part is not covered by the gate electrode, and wherein along the horizontal direction, the first part has a first length, the second part has a second length, and the second length is adjustable for adjusting a breakdown voltage of the LDMOS.

2. The LDMOS of claim 1, wherein the second length is greater than the first length.

3. The LDMOS of claim 1, wherein the first length is a fixed value.

4. The LDMOS of claim 1, wherein the second length is 2 to 5 times of the first length.

5. The LDMOS of claim 1, further comprising:
a silicide block layer covering and contacting the gate electrode and an entirety of a top surface of the second part, wherein the silicide block layer comprises a third part which does not overlap the gate electrode along the vertical direction, and the third part comprises a third length along the horizontal direction; and
a polysilicon layer covering and contacting the silicide block layer, wherein the polysilicon layer comprises a fourth part which does not overlap the gate electrode along the vertical direction, and wherein the fourth part comprises a fourth length along the horizontal direction, and the third length and the fourth length are both adjusted in the same scale as the second length is adjusted.

6. The LDMOS of claim 5, wherein the fourth length is smaller than the third length.

7. The LDMOS of claim 5, wherein the fourth length is equal to the third length.

8. The LDMOS of claim 1, further comprising:
a silicide block layer covering and contacting the gate electrode and an entirety of a top surface of the second part, wherein the silicide block layer comprises a third part which does not overlap the gate electrode along the vertical direction, and wherein the third part comprises a third length along the horizontal direction, and the third length is adjusted in the same scale as the second length is adjusted.

9. The LDMOS of claim 1, wherein along the horizontal direction, the first gate dielectric layer comprises a fifth length, and the fifth length is a fixed value.

10. The LDMOS of claim 1, wherein an end of the second part overlaps an edge of the drain.

11. A fabricating method of a laterally diffused metal oxide semiconductor
(LDMOS), comprising:
providing a substrate, wherein a horizontal direction is parallel to a top surface of the substrate, and a vertical direction is perpendicular to the top surface of the substrate;
forming a second gate dielectric material layer covering the substrate;
patterning the second gate dielectric material layer to form a second gate dielectric layer;
after forming the second gate dielectric layer, forming a first gate dielectric material layer to cover the substrate;
patterning the first gate dielectric material layer to form a first gate dielectric layer which is connected to the second gate dielectric layer, wherein a thickness of the second gate dielectric layer is greater than a thickness of the first gate dielectric layer;
forming a gate electrode covering the first gate dielectric layer and the second gate dielectric layer; and
forming a source and a drain respectively embedded in the substrate at two sides of the gate electrode; wherein the second gate dielectric layer has a first part and a second part, the second part is extended toward the drain along the horizontal direction, the first part is covered by the gate electrode, and the second part is not covered by the gate electrode, and wherein along the horizontal direction, the first part has a first length, the second part has a second length, and the second length is adjustable for adjusting a breakdown voltage of the LDMOS.

12. The fabricating method of an LDMOS of claim 11, further comprising:
after forming the source and the drain, forming a silicide block layer covering and contacting the gate electrode and an entirety of a top surface of the second part, wherein the silicide block layer comprises a third part which does not overlap the gate electrode, and the third part comprises a third length along the horizontal direction; and
after forming the silicide block layer, forming a polysilicon layer covering and contacting the silicide block layer, wherein the polysilicon layer comprises a fourth part which does not overlap the gate electrode, and wherein the fourth part comprises a fourth length along the horizontal direction, and the third length and the fourth length are both adjusted in the same scale as the second length is adjusted.

13. The fabricating method of an LDMOS of claim 12, wherein the fourth length is smaller than the third length.

14. The fabricating method of an LDMOS of claim 12, wherein the fourth length is equal to the third length.

15. The fabricating method of an LDMOS of claim 11, further comprising:
after forming the source and the drain, forming a silicide block layer covering and contacting the gate electrode and an entirety of a top surface of the second part, wherein the silicide block layer comprises a third part which does not overlap the gate electrode, the third part comprises a third length along the horizontal direction, and the third length is adjusted in the same scale as the second length is adjusted.

16. The fabricating method of an LDMOS of claim 11, wherein the second length is greater than the first length.

17. The fabricating method of an LDMOS of claim 11, wherein the first length is a fixed value.

18. The fabricating method of an LDMOS of claim 11, wherein the second length is 2 to 5 times of the first length.

19. The fabricating method of an LDMOS of claim 11, wherein along the horizontal direction, the first gate dielectric layer comprises a fifth length, and the fifth length is a fixed value.

20. The fabricating method of an LDMOS of claim 11, wherein an end of the second part overlaps an edge of the drain.
